(19) United States
(12) Patent Application Publication
(10) Pub. No.: US 2024/0055235 A1
(43) Pub. Date: Feb. 15, 2024

(54) SUBSTRATE PROCESSING APPARATUS AND SUBSTRATE PROCESSING METHOD

(71) Applicant: TOKYO ELECTRON LIMITED, Tokyo (JP)

(72) Inventors: Naoki MATSUMOTO, Miyagi (JP); Masataka MASUYAMA, Miyagi (JP); Naoki MIHARA, Miyagi (JP)

(21) Appl. No.: 18/383,602

(22) Filed: Oct. 25, 2023

Related U.S. Application Data
(63) Continuation of application No. PCT/JP2022/018220, filed on Apr. 19, 2022.

(30) Foreign Application Priority Data
Apr. 26, 2021 (JP) 2021-074292

(51) Int. Cl. H01J 37/32; H05B 6/10; H05B 6/44

(52) U.S. Cl. CPC H01J 37/32522; H05B 6/105; H05B 6/44; H01J 2237/002

(57) ABSTRACT

A substrate processing apparatus for processing a substrate includes: a processing chamber in which a processing space for the substrate is formed; a heating mechanism that adjusts an inner temperature of the processing chamber; and an inner member provided inside the processing chamber, wherein the heating mechanism includes an induction heating element that heats at least the inner member by generating heat with an induction magnetic field, and a magnetic field generator that generates the induction magnetic field.

### CROSS-REFERENCE TO RELATED APPLICATIONS

This application is a bypass continuation application of international application No. PCT/JP2022/018220 having an international filing date of Apr. 19, 2022 and designating the United States, the international application being based upon and claiming the benefit of priority from Japanese Patent Application No. 2021-074292, filed on Apr. 26, 2021, the entire contents of which are incorporated herein by reference.

### TECHNICAL FIELD

The present disclosure relates to a substrate processing apparatus and a substrate processing method.

### BACKGROUND

Patent Document 1 discloses a processing apparatus for executing a thermal treatment on a processing target object. The processing apparatus described in Patent Document 1 has a processing container in which an inner space is a processing space of the processing target object, and a container heating section for heating a sidewall of the processing container to a hot wall state. The container heating section includes a rod-shaped cartridge heater embedded in the sidewall of the processing container, and a heater power source connected to the cartridge heater.

### PRIOR ART DOCUMENT

### Patent Document

Patent Document 1: Japanese Laid-Open Patent Publication No. 2009-144211

### SUMMARY

A technique according to the present disclosure provides a substrate processing apparatus capable of wirelessly adjusting a temperature of an inner wall surface of a processing space in which substrate processing is performed.

According to an aspect of the present disclosure, a substrate processing apparatus for processing a substrate includes: a processing chamber in which a processing space for the substrate is formed; a heating mechanism that adjusts an inner temperature of the processing chamber; and an inner member provided inside the processing chamber, wherein the heating mechanism includes an induction heating element that heats at least the inner member by generating heat with an induction magnetic field, and a magnetic field generator that generates the induction magnetic field.

According to the present disclosure, it is possible to provide a substrate processing apparatus capable of wirelessly adjusting a temperature of an inner wall surface of a processing space in which substrate processing is performed.

### BRIEF DESCRIPTION OF DRAWINGS

FIG. 1 is a vertical cross-sectional view illustrating a configuration example of a plasma processing system according to a present embodiment.

FIG. 2 is a vertical cross-sectional view illustrating a configuration example of a heating mechanism according to the present embodiment.

FIG. 3 is an explanatory diagram illustrating an operating principle of the heating mechanism.

FIG. 4 is a schematic cross-sectional diagram illustrating a disposition example of the heating mechanism.

FIG. 5 is a schematic cross-sectional diagram illustrating another disposition example of the heating mechanism.

FIG. 6 is a schematic cross-sectional diagram illustrating a disposition example of a magnetic substance with respect to a shield member.

FIG. 7 is a vertical cross-sectional view illustrating another configuration example of the heating mechanism.

FIG. 8 is an explanatory diagram illustrating an operation example of the heating mechanism illustrated in FIG. 7.

FIG. 9 is a vertical cross-sectional view illustrating yet another configuration example of the heating mechanism.

FIG. 10 is a vertical cross-sectional view illustrating still another configuration example of the heating mechanism.

FIG. 11 is a vertical cross-sectional view illustrating yet another configuration example of the heating mechanism.

FIG. 12 is a vertical cross-sectional view illustrating still another configuration example of the heating mechanism.

FIG. 13 is a vertical cross-sectional view illustrating yet another configuration example of the heating mechanism.

FIG. 14 is a vertical cross-sectional view illustrating still another configuration example of the heating mechanism.

FIG. 15 is a vertical cross-sectional view illustrating yet another configuration example of the heating mechanism.

FIG. 16 is a vertical cross-sectional view illustrating still another disposition example of the heating mechanism.

FIG. 17 is a vertical cross-sectional view illustrating yet another disposition example of the heating mechanism.

FIG. 18 is a vertical cross-sectional view illustrating another configuration example of a shutter mechanism.

FIG. 19 is a perspective view illustrating yet another configuration example of the shutter mechanism.

### DETAILED DESCRIPTION

In a process of manufacturing a semiconductor device, various types of plasma processing such as an etching process, a film formation process, a diffusion process, and the like are performed on a semiconductor substrate (hereinafter, simply referred to as “substrate”) supported by a substrate support by exciting a processing gas supplied into a chamber to generate plasma.

In this plasma processing, a temperature of a sidewall body defining an inner wall surface of the chamber may be adjusted to uniformly control an atmosphere temperature of a processing space in which the plasma processing is performed, or to reduce adhesion of reaction products (hereinafter, referred to as “deposition”) to the inner wall surface of the chamber. The temperature adjustment of the sidewall body is performed by, for example, a rod-shaped heater provided inside the sidewall body, as disclosed in Patent Document 1.

Here, since the sidewall body of the chamber, which is a temperature adjustment target, is a metal partition wall that separates a vacuum space inside the chamber and an atmospheric space outside the chamber, a heater power source that supplies power to the heater provided inside the sidewall body is mainly installed in the atmospheric space outside the chamber.

However, in a case where the heater power source is installed in the atmospheric space outside the chamber in this manner, since it is necessary to transfer heat from the atmospheric space to the vacuum space, energy efficiency is deteriorated. Further, in addition to heat emission to the atmospheric space and heat transfer to a peripheral unit (for example, a transfer system) from the sidewall body of the chamber which is a temperature adjustment target, the sidewall body itself, which is a metal partition wall, has a large heat capacity, and thus an enormous time or energy is required to adjust the temperature to a desired temperature. In this manner, in the method of adjusting the temperature of the sidewall body in the related art, in addition to the fact that it is difficult to raise the temperature of the sidewall body, there is room for improvement in view of the low energy efficiency.

Further, in a case of adjusting the temperature of the sidewall body of the chamber by heating of the heater in this manner, the heater which is a heating element and the heater power source need to be electrically connected to each other through a power feeding cable or the like. Meanwhile, in a case where the heater and the heater power source are connected by using the power feeding cable in this manner, there is a possibility that some of radio-frequency waves applied from a radio frequency (RF) power source to an electrode for generating plasma enter the power feeding cable as a common mode noise when the plasma is generated. In this case, an abnormal discharge or a backflow of the radio-frequency power occurs in the heater power source system, and thus the plasma processing cannot be appropriately executed, or there is a case where the power feeding cable causes contamination in the processing space.

The technique according to the present disclosure is made in consideration of the circumstances described above, and provides a substrate processing apparatus capable of wirelessly adjusting a temperature of an inner wall surface of a processing space in which substrate processing is performed. Hereinafter, a plasma processing system as the substrate processing apparatus according to the present embodiment will be described with reference to the drawings. The same reference numerals will be given to elements having substantially the same functional configurations throughout the specification and the drawings, and redundant description thereof will be omitted.

### <Plasma Processing Apparatus>

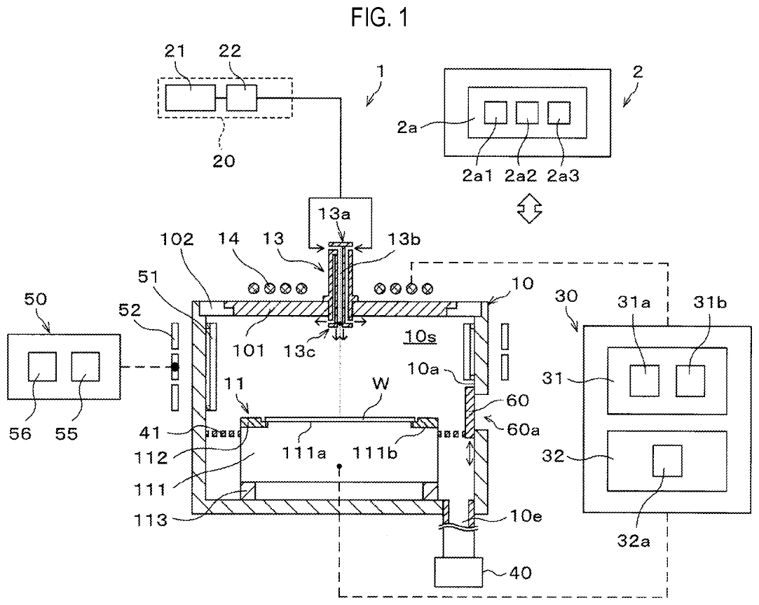

First, a plasma processing system according to a present embodiment will be described. FIG. 1 is a vertical cross-sectional view illustrating a configuration of the plasma processing system according to the present embodiment.

The plasma processing system includes an inductively-coupled plasma processing apparatus 1 and a controller 2. The plasma processing apparatus 1 includes a plasma processing chamber 10, a gas supply 20, a power source 30, an exhaust system 40, and a heating mechanism 50. The plasma processing chamber 10 includes a dielectric window 101 and a shutter 60 that opens and closes a loading port 60a of a substrate (wafer) W. In one embodiment, the dielectric window 101 is connected to an upper portion of a sidewall 10a of the plasma processing chamber 10 via an insulator ring 102, and constitutes at least a part of a ceiling portion (ceiling) of the plasma processing chamber 10. Further, the plasma processing apparatus 1 includes a substrate support 11, a gas introduction unit, and an antenna 14. The substrate support 11 is disposed inside the plasma processing chamber 10. The antenna 14 is disposed on or above the plasma processing chamber 10 (that is, on or above the dielectric window 101). The heating mechanism 50 includes, for example, a shield member 51 disposed along the sidewall 10a, inside the plasma processing chamber 10. A plasma processing space 10s defined by the dielectric window 101, the shield member 51 of the heating mechanism 50, and the substrate support 11 is formed inside the plasma processing chamber 10. The plasma processing chamber 10 has at least one gas supply port for supplying at least one processing gas into the plasma processing space 10s, and at least one gas exhaust port for exhausting the gas from the plasma processing space 10s.

The substrate support 11 includes a main body member 111 and a ring assembly 112. The main body member 111 is fixed to a bottom surface portion of the plasma processing chamber 10 via a support member 113. An upper surface of the main body member 111 has a central region 111a (substrate support surface) for supporting the substrate W, and an annular region 111b (ring support surface) for supporting the ring assembly 112. The annular region 111b surrounds the central region 111a in a plan view. The substrate W is disposed on the central region 111a, and the ring assembly 112 is disposed on the annular region 111b to surround the substrate W on the central region 111a.

In one embodiment, the main body member 111 includes a base (not illustrated) and an electrostatic chuck (not illustrated). The base includes a conductive member. The conductive member of the base functions as a lower electrode. The electrostatic chuck is disposed on the base. An upper surface of the electrostatic chuck has the central region 111a and the annular region 111b described above. The ring assembly 112 includes one or more annular members, and at least one of the one or more annular members is an edge ring.

Further, although not illustrated, the substrate support 11 may include a temperature control module configured to adjust at least one among the electrostatic chuck, the ring assembly 112, and the substrate W to a target temperature. The temperature control module may include a heater, a heat transfer medium, a flow path, or a combination thereof. A heat transfer fluid, such as brine or gas, flows through the flow path. Further, the substrate support 11 may include a heat transfer gas supply configured to supply a heat transfer gas between the rear surface of the substrate W and the central region 111a (substrate support surface).

The gas introduction unit is configured to introduce at least one processing gas from the gas supply 20 into the plasma processing space 10s. In one embodiment, the gas introduction unit includes a center gas injector (CGI) 13. The center gas injector 13 is disposed above the substrate support 11 and attached to a center opening formed in the dielectric window 101. The center gas injector 13 has at least one gas supply port 13a, at least one gas flow path 13b, and at least one gas introduction port 13c. The processing gas supplied to the gas supply port 13a passes through the gas flow path 13b and is introduced into the plasma processing space 10s from the gas introduction port 13c. The gas introduction unit may include one or a plurality of side gas injectors (SGIs) attached to one or a plurality of openings formed at the sidewall 10a, in addition to or instead of the center gas injector 13.

The gas supply 20 may include at least one gas source 21 and at least one flow rate controller 22. In one embodiment, the gas supply 20 is configured to supply at least one processing gas from the respective corresponding gas sources 21 to the center gas injector 13 via the respective corresponding flow rate controllers 22. Each flow rate controller 22 may include, for example, a mass flow controller or a pressure-controlled flow rate controller. Further, the gas supply 20 may include one or more flow rate modulation devices that modulate or pulse flow rates of at least one processing gas.

The power source 30 includes an RF power source 31 coupled to the plasma processing chamber 10 via at least one impedance matching circuit. The RF power source 31 is configured to supply at least one RF signal (RF power), such as a source RF signal and a bias RF signal, to a conductive member (the lower electrode) of the substrate support 11 and/or the antenna 14. Accordingly, plasma is formed from at least one processing gas supplied into the plasma processing space 10s. Accordingly, the RF power source 31 may function as at least a part of a plasma generator configured to generate plasma from one or more processing gases in the plasma processing chamber 10. In addition, by supplying the bias RF signal to the lower electrode, a bias potential can be generated in the substrate W to draw an ion component in the formed plasma to the substrate W.

In one embodiment, the RF power source 31 includes a first RF generator 31a and a second RF generator 31b. The first RF generator 31a is configured to be coupled to the antenna 14, and generate a source RF signal (source RF power) for plasma generation via at least one impedance matching circuit. In one embodiment, the source RF signal has a frequency in a range of 13 MHz to 150 MHz. In one embodiment, the first RF generator 31a may be configured to generate a plurality of source RF signals having different frequencies. The generated one or more source RF signals are supplied to the antenna 14.

The second RF generator 31b is coupled to the lower electrode via at least one impedance matching circuit, and is configured to generate the bias RF signal (bias RF power). In one embodiment, the bias RF signal has a lower frequency than that of the source RF signal. In one embodiment, the bias RF signal has a frequency within a range of 400 kHz to 13.56 MHz. In one embodiment, the second RF generator 31b may be configured to generate a plurality of bias RF signals having different frequencies. The generated one or the plurality of bias RF signals are supplied to the lower electrode. In addition, in various embodiments, at least one of the source RF signal and the bias RF signal may be pulsed.

Further, the power source 30 may include a DC power source 32 coupled to the plasma processing chamber 10. The DC power source 32 includes a bias DC generator 32a. In one embodiment, the bias DC generator 32a is configured to be connected to the lower electrode, and generate a bias DC signal. The generated bias DC signal is applied to the lower electrode. In one embodiment, the bias DC signal may be applied to another electrode, such as an electrode inside an electrostatic chuck. In various embodiments, the bias DC signal may be pulsed. The bias DC generator 32a may be provided in addition to the RF power source 31, or may be provided instead of the second RF generator 31b.

The antenna 14 includes one or more coils. In one embodiment, the antenna 14 may include an outer coil and an inner coil that are coaxially disposed. In this case, the RF power source 31 may be connected to both the outer coil and the inner coil, or may be connected to any one of the outer coil and the inner coil. In the former case, the same RF generator may be connected to both the outer coil and the inner coil, or separate RF generators may be connected to the outer coil and the inner coil, respectively.

The exhaust system 40 may be connected to, for example, a gas exhaust port 10e disposed at a bottom portion of the plasma processing chamber 10. The exhaust system 40 may include a pressure adjusting valve and a vacuum pump. A pressure inside the plasma processing space 10s is adjusted by the pressure adjusting valve. The vacuum pump may include a turbo molecular pump, a dry pump, or a combination thereof.

Further, in one embodiment, the exhaust system 40 includes a baffle plate 41 disposed to partition the plasma processing space 10s and the gas exhaust port 10e around the substrate support 11 in a plan view. The baffle plate 41 is an annular plate-shaped member having a large number of through-holes. The baffle plate 41 communicates the plasma processing space 10s and the gas exhaust port 10e via the through-holes, and reduces a leakage to the gas exhaust port 10e by capturing or reflecting the plasma generated in the plasma processing space 10s. Further, the baffle plate 41 is disposed in parallel with the substrate W placed on the substrate support 11, and is disposed at a position lower than an upper surface of the substrate W in FIG. 1.

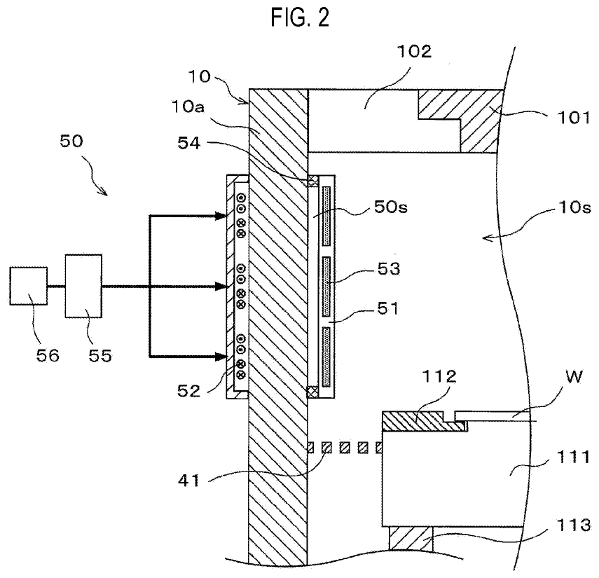

FIG. 2 is a vertical cross-sectional view schematically illustrating a configuration of the heating mechanism 50. As illustrated in FIG. 2, the heating mechanism 50 includes a shield member 51 disposed inside the plasma processing chamber 10 along the sidewall 10a of the plasma processing chamber 10, a plurality of induction heating coils 52 disposed along an outer wall surface of the sidewall 10a outside the sidewall 10a (on a side of the atmospheric space), and a plurality of magnetic substances 53 disposed inside the shield member 51 corresponding to the respective induction heating coils 52.

The shield member 51 is made of, for example, a nonmagnetic dielectric such as ceramic or a member having high thermal conductivity such as Al. The shield member 51 is disposed to cover the sidewall 10a inside the plasma processing chamber 10, and functions substantially as an inner wall surface of the plasma processing space 10s. Further, the shield member 51 is disposed to be spaced apart from the sidewall 10a, and end portions (upper end portion and lower end portion in FIG. 2) of the shield member 51 are connected to the sidewall 10a via a sealing member 54 having heat insulating properties. A space having a desired width surrounded by the sidewall 10a, the shield member 51, and the sealing member 54 can be maintained in, for example, a vacuum atmosphere. In other words, the shield member 51 and the sidewall 10a are thermally separated from each other by a vacuum heat insulating space 50s serving as a heat insulating layer and the sealing member 54.

The shield member 51 is heated by heat generation of a magnetic substance 53 to be described later, and is maintained in a hot wall state at a desired temperature. In this case, in order to reduce the amount of energy required to heat the shield member 51 to the desired temperature, it is preferable that the shield member 51 be formed as thin as possible to have a thickness with which the magnetic substance 53 can be disposed inside the shield member 51. In other words, it is preferable to form the shield member 51, which is a temperature adjustment target, to be thin to reduce a heat capacity.

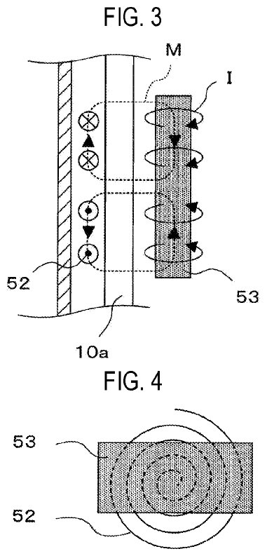

The plurality of induction heating coils 52 serving as magnetic field generators are provided along the outer wall surface of the sidewall 10a of the plasma processing chamber 10. At least one inverter circuit 55 and at least one heating power source 56 are connected to the plurality of induction heating coils 52. The induction heating coil 52 is connected to the heating power source 56 via the inverter circuit 55. The induction heating coil 52 generates an induction magnetic field M as illustrated in FIG. 3 by receiving power from the heating power source 56.

The inverter circuit 55 controls a frequency of the power applied from the heating power source 56 to the induction heating coil 52. Specifically, for example, an alternating current 50/60 Hz from the heating power source 56 is converted into a radio-frequency wave of several tens of kHz or more (for example, 100 kHz to 2 MHz). As the heating power source 56, any alternating current (AC) power source, for example, a general commercial AC power source, can be used. As illustrated in FIG. 2, only one inverter circuit 55 and one heating power source 56 may be connected to the heating mechanism 50, or a plurality of inverter circuits 55 and heating power sources 56 may be provided, for example, for each temperature control region for adjusting an atmosphere temperature of a plasma processing space 10s.

The magnetic substance 53 serving as an induction heating element is made of, for example, a metal material having magnetism (for example, a material containing iron such as carbon steel, silicon steel, stainless steel, permalloy, and ferrite), and is integrally configured with the shield member 51 by being provided inside the shield member 51. As illustrated in FIG. 3, an induction current I (eddy current) is induced at a surface of the magnetic substance 53 by the induction magnetic field M generated from the induction heating coil 52. The magnetic substance 53 generates Joule heat according to a resistance value of the magnetic substance 53 by the induction current I. Further, induction magnetic flux generated from the induction heating coil 52 generates heat by a hysteresis loss (loss caused by friction between molecules of Fe) generated in the magnetic substance 53.

The induction heating element may not be a metal material having magnetism as long as the induction heating element is a material capable of generating sufficient heat by Joule heat generation caused by the eddy current. For example, aluminum, tungsten, tin, titanium, carbon, silicon, or silicon carbide may be used.

In the heating mechanism 50, in order to appropriately heat the magnetic substance 53 by the induction magnetic field M emitted from the induction heating coil 52, a core member made of a material having a high magnetic permeability may be provided in the induction heating coil 52 to strengthen the induction magnetic field M emitted from the induction heating coil 52.

Further, as illustrated in FIG. 4, in order to appropriately apply the induction magnetic field M emitted from the induction heating coil 52 to the magnetic substance 53, the induction heating coil 52 and the magnetic substance 53 are disposed such that at least parts of the induction heating coil 52 and the magnetic substance 53 overlap with each other in a front view, preferably, such that an entire surface of the induction heating coil 52 overlaps with the magnetic substance 53 as illustrated in FIG. 5. When the induction heating coil 52 and the magnetic substance 53 are disposed to overlap with each other in this manner, the induction magnetic field M emitted from the induction heating coil 52 can be caused to act on the magnetic substance 53 appropriately, so that the magnetic substance 53 can generate heat. Further, when the induction heating coil 52 and the magnetic substance 53 are disposed such that the entire surface of the induction heating coil 52 overlaps with the magnetic substance 53 as illustrated in FIG. 5, the induction magnetic field M emitted to at least a side of the magnetic substance 53 from the induction heating coil 52 can be used for induction heating without leakage.

Further, in the plasma processing apparatus 1, for example, in order to improve uniformity of process characteristics with respect to the substrate W in the plasma processing, it is required to control an atmosphere temperature in the plasma processing space 10s to be uniform, as described above. Meanwhile, in the plasma processing apparatus 1, for example, a distribution of the atmosphere temperature in the plasma processing space 10s may become biased by various conditions such as a geometric positional relationship of the various members disposed in the plasma processing space 10s or the conditions of the processing process.

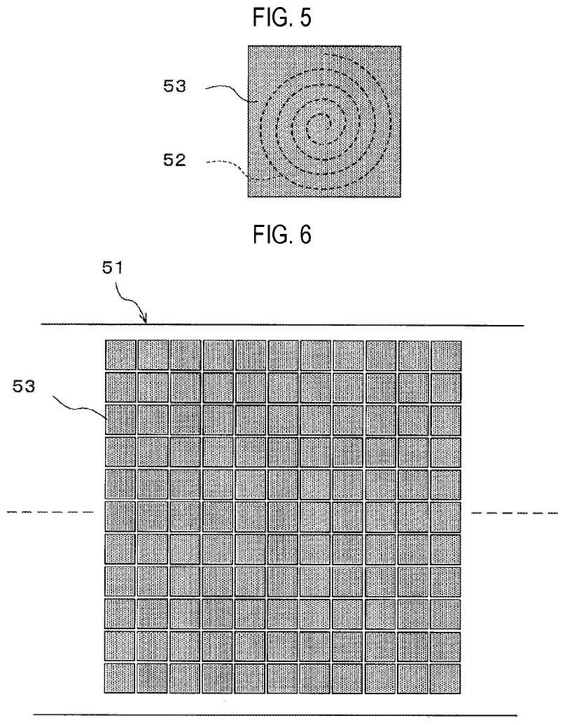

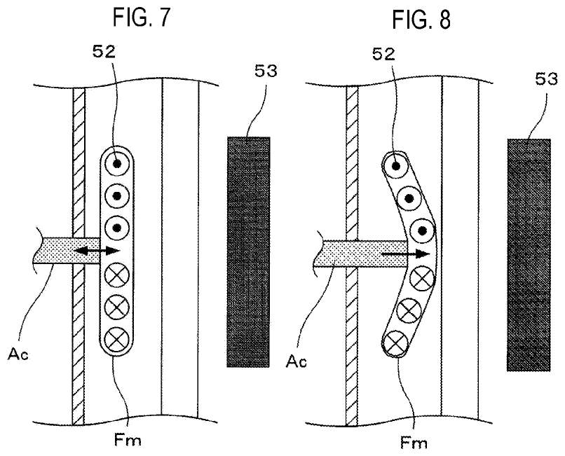

Accordingly, as described above, the plurality of magnetic substances 53 are provided in the shield member 51 of the present embodiment. Specifically, as illustrated in FIG. 6, the plurality of magnetic substances 53 are provided inside the shield member 51 at desired intervals from each other. Further, the plurality of induction heating coils 52 are provided outside the plasma processing chamber 10 to correspond to the plurality of magnetic substances 53 on a one-to-one basis. When the shield member 51 is heated (adjustment of the atmosphere temperature of the plasma processing space 10s), a distribution of a surface temperature (the atmosphere temperature of the plasma processing space 10s) of the shield member 51 can be appropriately adjusted, by adjusting a frequency of the radio-frequency power applied to each of the induction heating coils 52 provided to correspond to each of the magnetic substances 53 (or each of the temperature control regions formed by a group of induction heating coils 52) by the inverter circuit 55. Further, from the viewpoint of appropriately adjusting the distribution of the atmosphere temperature in the plasma processing space 10s, a movable mechanism may be further provided which causes a part of the magnetic field generator to come close to or separate from the induction heating element. Specifically, for example, as illustrated in FIG. 7, an actuator Ac may be connected to a central portion of the induction heating coil 52.

The induction heating coil 52 is covered with an insulator film Fm such as a polyimide film, and the actuator Ac and the induction heating coil 52 are insulated from each other. The actuator Ac may be made of an insulator such as quartz, and insulated from the induction heating coil 52. A distal end of the actuator Ac is bonded to the insulator film Fm, and a part of the induction heating coil 52 (the central portion of the induction heating coil 52 in the example illustrated in FIG. 8) comes close to or is separated from the induction heating element (the magnetic substance 53) by the driving of the actuator Ac.

When the part (central portion) of the induction heating coil 52 is brought close to the magnetic substance 53, a close portion (central portion) of the magnetic substance 53 is heated more strongly than a distant portion (end portion) of the magnetic substance 53. Meanwhile, since the part (central portion) of the induction heating coil 52 is separated from the magnetic substance 53, the distant portion (central portion) of the magnetic substance 53 is heated weaker than the close portion (end portion) of the magnetic substance 53.

Accordingly, by providing a movable mechanism that causes a part of the magnetic field generator to come close to or separate from the induction heating element, the temperature distribution control of the induction heating element (in the examples illustrated in FIGS. 7 and 8, the magnetic substance 53) can be performed. As illustrated in FIG. 6, in a case of providing a plurality of magnetic field generators, each of all the magnetic field generators may be provided with a movable mechanism, or only some of the magnetic field generators may be provided with a movable mechanism. Further, the movable mechanism may be provided for each temperature control region formed with a group of magnetic field generators, or for only a part of the temperature control region formed by the group of magnetic field generators.

In this manner, in the heating mechanism 50 provided in the plasma processing apparatus 1 of the present embodiment, the shield member 51 disposed inside the sidewall 10a is heated without directly heating the sidewall 10a of the plasma processing chamber 10. At this time, since the shield member 51 is disposed to be thermally insulated from the sidewall 10a and is formed to have a small thickness to have a small heat capacity, the amount of energy required for forming and maintaining the hot wall state during the plasma processing can be significantly reduced as compared with the related art.

Further, since it is easy to adjust the temperature of the shield member 51 forming the inner wall of the plasma processing space 10s in this manner, it is possible to easily control an adhesion state of the dissociated deposition or the reaction products (hereinafter, collectively referred to as “deposition”) from the processing gas to the shield member 51 during the plasma processing. That is, for example, by maintaining the temperature of the shield member 51 at a high temperature, it is possible to appropriately suppress the adhesion of the deposition to the shield member 51.

Further, in the present embodiment, the magnetic substance 53 provided inside the shield member 51 can be inductively heated wirelessly by using the induction magnetic field M emitted from the induction heating coil 52 without being electrically connected to the induction heating coil 52 provided outside the plasma processing chamber 10. That is, it is possible to reduce the number of power feeding cables that connect the heating element and the power source in the temperature adjusting section of the plasma processing chamber in the related art.

As described above, in the related art, the bias RF signal supplied from the RF power source 31 to the lower electrode during the plasma processing may enter the power feeding cable that connects the heating element (for example, a heater or the like) and the heater power source as common mode noise. In this respect, in the present embodiment, since the power feeding cable that connects the induction heating coil 52 and the magnetic substance 53 can be omitted as described above, no noise component enters the heating power source system via the power feeding cable as in the related art. In particular, in the present embodiment, since the induction heating coil 52 and the heating power source 56 for generating the induction magnetic field M are provided outside the plasma processing chamber 10, the introduction of noise components into the heating power source system is also appropriately suppressed.

Further, in the present embodiment, since it is not necessary to connect the power feeding cable to the magnetic substance 53 in this manner, in other words, since it is not necessary to dispose the power feeding cable in the vacuum space, the power feeding cable does not cause contamination.

Referring back to FIG. 1, the controller 2 processes computer-executable instructions for instructing the plasma processing apparatus 1 to execute various steps described herein below. The controller 2 may be configured to control the respective components of the plasma processing apparatus 1 to execute the various steps described herein below. In an embodiment, part or all of the controller 2 may be included in the plasma processing apparatus 1. The controller 2 may include, for example, a computer 2a. The computer 2a may include, for example, a processor (central processing unit (CPU)) 2a1, a storage unit 2a2, and a communication interface 2a3. The processor 2a1 may be configured to perform various control operations based on a program stored in the storage unit 2a2. The storage unit 2a2 may include a random access memory (RAM), a read only memory (ROM), a hard disk drive (HDD), a solid state drive (SSD), or a combination thereof. The communication interface 2a3 may communicate with the plasma processing apparatus 1 through a communication line such as a local area network (LAN).

While various exemplary embodiments have been described above, various additions, omissions, substitutions and changes may be made without being limited to the exemplary embodiments described above. Indeed, the embodiments described herein may be embodied in a variety of other forms.

For example, although the present embodiment has been described by taking a case where the plasma processing system includes the plasma processing apparatus 1 of inductively-coupled plasma (ICP) as an example, the configuration of the plasma processing system is not limited thereto. For example, the plasma processing system may include a processing apparatus that includes a plasma generator of, for example, a capacitively coupled plasma (CCP), an electron-cyclotron-resonance plasma (an ECR plasma), a helicon wave plasma (HWP), or a surface wave plasma (SWP). Further, a processing apparatus including various types of plasma generators including an alternating current (AC) plasma generator and a direct current (DC) plasma generator may be used.

### <Processing Method of Substrate by Plasma Processing Apparatus>

Next, an example of the processing method of the substrate W in the plasma processing apparatus 1 configured as above will be described. With the plasma processing apparatus 1, any plasma processing such as an etching process, a film formation process, a diffusion process, and the like according to purposes is performed on the substrate W.

First, the shutter 60 is opened, the substrate W is loaded into the plasma processing chamber 10, and the substrate W is placed on the electrostatic chuck of the substrate support 11. When the substrate W is placed on the electrostatic chuck, the shutter 60 is closed, and the inside of the plasma processing chamber 10 is sealed. Next, a voltage is applied to the adsorption electrode of the electrostatic chuck, and thus the substrate W is adsorbed and held by the electrostatic power on the electrostatic chuck.

When the substrate W is adsorbed and held onto the electrostatic chuck, the inside of the plasma processing chamber 10 is decompressed to a predetermined vacuum level. Next, the processing gas is supplied from the gas supply 20 to the plasma processing space 10s via the center gas injector 13. Further, the source RF power for plasma generation is supplied from the first RF generator 31a to the antenna 14, and thus the processing gas is excited to generate plasma. At this time, the bias RF power may be supplied from the second RF generator 31b to the lower electrode. In the plasma processing space 10s, the plasma processing according to purposes is executed on the substrate W by the action of the generated plasma.

During the plasma processing of the substrate W, the atmosphere temperature in the plasma processing space 10s is adjusted by the operation of the heating mechanism 50 provided inside the shield member 51. Specifically, the surface temperature of the shield member 51 forming the inner wall surface of the plasma processing space 10s is adjusted by applying radio-frequency power from the heating power source 56 to the induction heating coil 52 to generate the induction magnetic field M, thereby inducing the induction current I (eddy current) on the surface of the magnetic substance 53 and inductively heating the magnetic substance 53, for example.

The surface temperature of the shield member 51 may be controlled to be constant in a series of plasma processing performed in the plasma processing apparatus 1, or may be controlled to be appropriately changed according to a processing step.

Specifically, for example, in a case where a deviation occurs in the atmosphere temperature of the plasma processing space 10s, the temperature control may be performed independently for each induction heating coil 52 (or for each of the temperature control regions described above) to eliminate the deviation in the atmosphere temperature and make the temperature of the plasma processing space 10s uniform across the entire plasma processing space 10s.

Further, for example, in the series of plasma processing in the plasma processing apparatus 1, the temperature control may be performed such that the surface temperature of the shield member 51 is high in a processing step in which the amount of generated deposition is large, and the temperature of the shield member 51 is low in a processing step in which the amount of generated deposition is small (lower than the surface temperature in the processing step in which the amount of generated deposition is large). The surface temperature of the shield member 51 can be controlled, for example, by adjusting a frequency of a current to be supplied to the induction heating coil 52 by the inverter circuit 55.

Further, the adjustment of the surface temperature of the shield member 51 may be started after the plasma processing in the plasma processing apparatus 1 is started in this manner, or may be started before the plasma processing is started.

When the plasma processing is ended, the supply of the source RF power from the first RF generator 31a and the supply of the processing gas from the gas supply 20 are stopped. In a case where the bias RF power is supplied during the plasma processing, the supply of the bias RF power is also stopped.

Next, the temperature adjustment of the shield member 51 by the heating mechanism 50 and the adsorption and holding of the substrate W by the electrostatic chuck are stopped, and static discharge of the substrate W and the electrostatic chuck after the plasma processing is performed. Thereafter, the substrate W is detached from the electrostatic chuck, and the substrate W is unloaded from the plasma processing apparatus 1. In this way, a series of plasma processing is completed.

### <Action and Effects of Substrate Support According to Present Disclosure>

As described above, with the plasma processing apparatus 1 according to the present embodiment, the shield member 51 forming the inner wall surface of the plasma processing space 10s is provided inside the plasma processing chamber 10, and the shield member 51 is heated by the heating mechanism 50 to control the atmosphere temperature of the plasma processing space 10s. Accordingly, since it is not necessary to heat the sidewall 10a of the plasma processing chamber 10, the amount of energy for forming and maintaining the inner wall surface of the plasma processing space 10s in a hot-wall state during the plasma processing can be substantially reduced, as compared with the related art, that is, the energy efficiency related to the plasma processing can be substantially improved.

Further, according to the present embodiment, the shield member 51 forming the inner wall surface of the plasma processing space 10s is provided to be thermally separated from the sidewall 10a of the plasma processing chamber 10 having a large heat capacity, and is formed to have a small thickness so as to reduce the heat capacity. Accordingly, heat generated by the heat generation of the magnetic substance 53 can be appropriately used for the heating of the shield member 51, a time required for the heating of the shield member 51 can be shortened, and a time required for the start-up of the plasma processing process can be substantially shortened.

Further, since the temperature adjustment of the shield member 51 (the inner wall surface of the plasma processing space 10s) can be easily performed in this manner, for example, the surface temperature of the shield member 51 can be adjusted according to a process of the plasma processing, so that the adhesion of the deposition to the shield member 51 can be easily controlled. That is, the plasma processing can be stably performed on the substrate W.

Further, according to the present embodiment, the magnetic substance 53 provided inside the shield member 51 can be inductively heated wirelessly by using the induction magnetic field M emitted from the induction heating coil 52 without being electrically connected to the induction heating coil 52 provided outside the plasma processing chamber 10. That is, it is possible to reduce the number of power feeding cables that connect the heating element and the power source in the temperature adjusting section of the plasma processing chamber in the related art. Accordingly, for example, a part of the radio-frequency power supplied from the RF power source 31 to the lower electrode during the plasma processing is suppressed from entering the heating power source system for generating the induction magnetic field M in the induction heating coil 52 as a noise component, and the risk of occurrence of abnormal discharge, a backflow of the radio-frequency current, or contamination due to the installation of the power feeding cable as in the related art can be appropriately reduced.

Further, according to the present embodiment, since it is not necessary to connect the power feeding cable or the like to the magnetic substance 53 in this manner, it is possible to further reduce installation of an RF cut filter provided in association with the power feeding cable for reducing the abnormal discharge or the backflow of the radio-frequency current described above, in the related art. Accordingly, it is possible to reduce a space for installing the RF cut filter, and to reduce the number of components of the heating mechanism 50 as compared with the related art, that is, to appropriately reduce a space or a cost for installing the heating mechanism 50.

Further, as illustrated in FIG. 6, the shield member 51 according to the present embodiment is configured such that the plurality of magnetic substances 53 are disposed side by side inside the shield member 51, and the frequency of the supply current is controlled by the inverter circuit for each induction heating coil 52 corresponding to each magnetic substance 53 (or for each temperature control region formed by the group of induction heating coils 52), and thus the temperature control can be performed independently for each induction heating coil 52 (for each temperature control region). Accordingly, for example, even in a case where a deviation occurs in the distribution of the atmosphere temperature in the plasma processing space 10s during the plasma processing, the deviation of the temperature distribution can be appropriately resolved, and the plasma processing can be appropriately performed on the substrate W.

As illustrated in FIG. 2, when the plurality of induction heating coils 52 are disposed side by side outside the plasma processing chamber 10 respectively corresponding to the plurality of magnetic substances 53, the induction magnetic fields M emitted from the induction heating coils 52 adjacent to each other may interfere with each other, and thus the magnetic substances 53 corresponding to each induction heating coils 52 may not be appropriately heated. Specifically, for example, the induction magnetic field M emitted from one induction heating coil 52 acts on the magnetic substance 53 provided to correspond to other induction heating coils 52 provided adjacent to the induction heating coil 52, and thus the magnetic substance 53 may not be appropriately heated.

Therefore, in order to reduce the interference of the induction magnetic field M, a magnetic shield 57 that reflects and absorbs the induction magnetic field M may be provided between the adjacent induction heating coils 52. As the magnetic shield 57, a plate-shaped member of a relative magnetic permeability μ>1, for example, stainless steel, can preferably be selected.

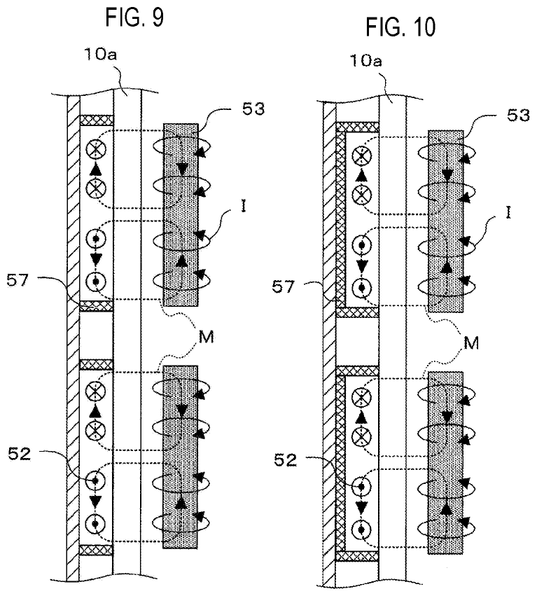

FIG. 9 is an explanatory diagram illustrating an installation example of the magnetic shield 57. As illustrated in FIG. 9, the magnetic shield 57 is provided between the induction heating coils 52 adjacent to each other. The magnetic shield 57 larger than a wire diameter of the induction heating coil 52 is provided. More specifically, the magnetic shield 57 is provided to surround the induction heating coil 52 in the front view. Accordingly, it is possible to reduce the induction magnetic field M emitted from the induction heating coil 52 from leaking in an adjacent direction, reduce the interference of the induction magnetic field M, and appropriately heat the magnetic substance 53 (the substrate W).

Further, as illustrated in FIG. 10, the magnetic shield 57 may be further disposed on a side opposite to the sidewall 10a (the magnetic substance 53) of the plasma processing chamber 10 (the atmospheric space side) along a surface direction of the induction heating coil 52. In other words, the magnetic shield 57 may be further disposed outside the plasma processing chamber 10 with the induction heating coil 52 interposed therebetween. In this manner, when the magnetic shield 57 is further provided on the side opposite to the magnetic substance 53 (the atmospheric space side) along the surface direction of the induction heating coil 52, a part of the induction magnetic field M emitted from the induction heating coil 52 toward the atmospheric space side can be reflected toward a side of the magnetic substance 53. Accordingly, it is possible to improve a directivity of the induction magnetic field M toward the side of the magnetic substance 53, and to further improve heating efficiency of the magnetic substance 53 (the shield member 51).

In the embodiment, a surface of the induction heating coil 52 other than the magnetic substance 53 is blocked by the magnetic shield 57 to improve the directivity of the induction magnetic field M with respect to the magnetic substance 53. Meanwhile, for example, when it is desired to improve the directivity of the induction magnetic field M with respect to another direction, an installation position of the magnetic shield 57 may be appropriately changed.

In the above embodiment, although the induction heating coils 52 are disposed side by side with respect to an entire surface of the shield member 51 as illustrated in FIG. 2 or FIG. 6, that is, the entire surface of the shield member 51 is configured to be temperature-adjustable, the disposition of the induction heating coils 52 is not limited thereto.

Specifically, when the magnetic substance 53 is disposed at least partially in the plane of the shield member 51, that is, at least partially on the inner wall surface of the plasma processing space 10s, the shield member 51 can be heated by the heat generation of the magnetic substance 53, so that the atmosphere temperature of the plasma processing space 10s can be adjusted.

In addition, in the above embodiment, for example, as illustrated in FIG. 2 or the like, the plurality of magnetic substances 53 are disposed to respectively correspond to the plurality of induction heating coils 52 disposed in the plane of the shield member 51 on a one-to-one basis. In other words, although the plasma processing apparatus 1 is installed with the same number of induction heating coils 52 and the magnetic substance 53, the respective numbers of the installed induction heating coils 52 and magnetic substance 53 are not limited thereto.

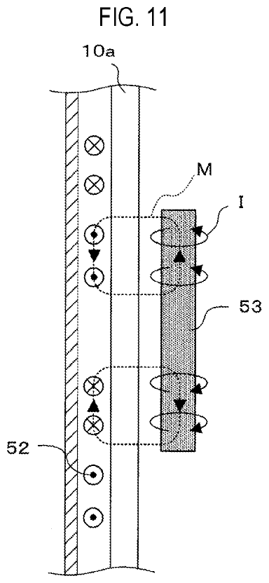

Specifically, as illustrated in FIG. 11, one magnetic substance 53 may be inductively heated by the plurality of (two in the illustrated example) induction heating coils 52. Accordingly, the number of the magnetic substances 53 disposed in the shield member 51 can be reduced, and the cost for installing the heating mechanism 50 can be reduced.

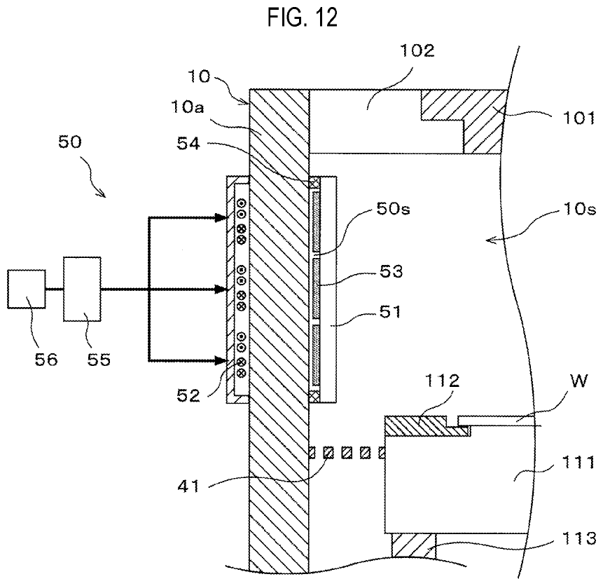

In the above embodiment, although a case where the magnetic substance 53 is disposed inside the shield member 51 is described by way of example, the configuration of the heating mechanism 50 is not limited thereto. For example, as illustrated in FIG. 12, the magnetic substance 53 may be configured separately from the shield member 51, and the magnetic substance 53 may be provided on a surface of the shield member 51 opposite to the plasma processing space 10s. In this case, the vacuum heat insulating space 50s described above is formed between the magnetic substance 53 and the sidewall 10a.

By providing the shield member 51 and the magnetic substance 53 separately in this manner, it is not necessary to provide the magnetic substance 53 inside, and thus the thickness of the shield member 51 can be further reduced. That is, the heating of the shield member 51 can be more efficiently performed. Even in a case where the shield member 51 and the magnetic substance 53 are separately configured in this manner, the vacuum heat insulating space 50s described above is formed between the magnetic substance 53 and the sidewall 10a, so that the heat transfer from the magnetic substance 53 to the sidewall 10a is reduced, and the heating of the shield member 51 can be more appropriately performed.

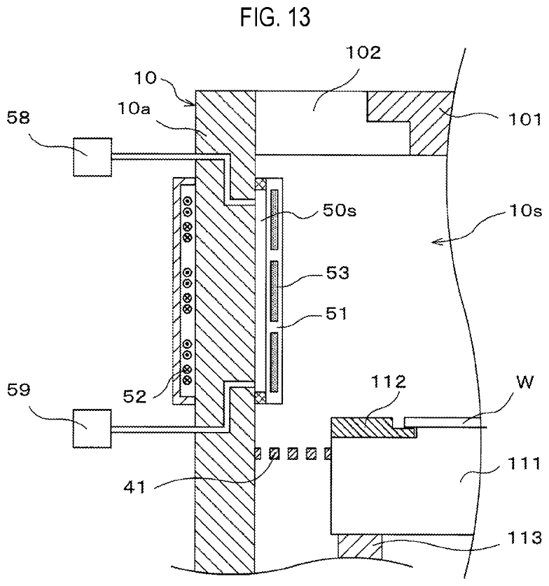

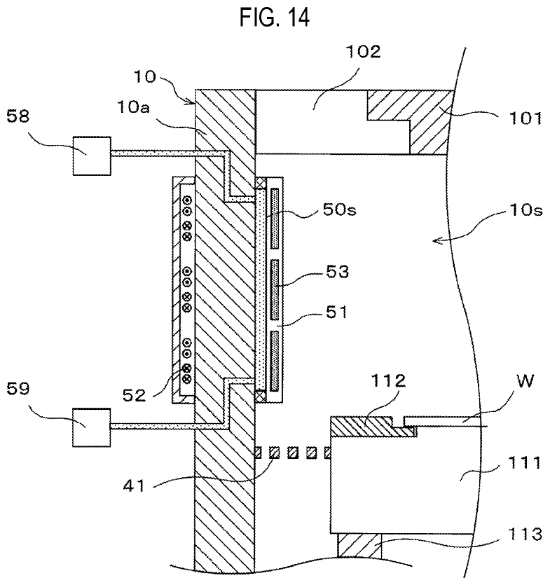

In the heating mechanism 50 according to the above embodiment, a heat transfer fluid (for example, brine or gas) may be allowed to flow through the vacuum heat insulating space 50s formed between the shield member 51 (the magnetic substance 53 in the example illustrated in FIG. 12) and the sidewall 10a of the plasma processing space 10s. In other words, as illustrated in FIGS. 13 and 14, a fluid supply 58 that supplies a heat transfer fluid L to the vacuum heat insulating space 50s, and a fluid exhausting portion 59 through which the heat transfer fluid L is exhausted from the vacuum heat insulating space 50s may be connected to the vacuum heat insulating space 50s.

In such a case, for example, as illustrated in FIG. 13, in a case where the heat transfer fluid L does not flow through the vacuum heat insulating space 50s (the vacuum heat insulating space 50s is in a vacuum state), the shield member 51 and the sidewall 10a are thermally separated from each other, and the shield member 51 can be efficiently heated by the heat generation of the magnetic substance 53.

Meanwhile, for example, in a case where the heat transfer fluid L flows through the vacuum heat insulating space 50s as illustrated in FIG. 14, the shield member 51 and the sidewall 10a are thermally connected to each other by the heat transfer fluid L. That is, heat transfer is generated from the heated shield member 51 to the sidewall 10a via the heat transfer fluid L, so that the shield member 51 can be cooled.

When the heat transfer fluid L is configured to flow through the vacuum heat insulating space 50s in this manner, by controlling the flow of the heat transfer fluid L, in addition to the heating for adjusting the temperature of the shield member 51, the cooling can be more appropriately performed. Accordingly, the surface temperature of the shield member 51 (the atmosphere temperature of the plasma processing space 10s) can be adjusted more appropriately, that is, the plasma processing can be performed more appropriately on the substrate W.

Instead of switching the heating and the cooling of the shield member 51 and the sidewall 10a by allowing the heat transfer fluid L to flow through the vacuum heat insulating space 50s in this manner, for example, the shield member 51 may be configured to be movable inside the plasma processing space 10s, so that the shield member 51 and the sidewall 10a can be brought into physical contact with each other. Accordingly, for example, in a case where the shield member 51 and the sidewall 10a are spaced apart from each other, the shield member 51 is heated, and in a case where the shield member 51 and the sidewall 10a are in contact with each other, the shield member 51 is cooled.

In the above embodiment, although the vacuum heat insulating space 50s serving as a heat insulating layer is formed between the shield member 51 and the sidewall 10a to thermally separate the shield member 51 and the sidewall 10a, the configuration of the heat insulating layer is not limited thereto. Specifically, for example, when the shield member 51 is connected to the sidewall 10a via a heat insulating member (not illustrated) serving as the heat insulating layer, the shield member 51 and the sidewall 10a also can be thermally separated from each other, that is, the heating of the shield member 51 can be efficiently performed.

However, in a case where the shield member 51 and the sidewall 10a are connected to each other via the heat insulating member in this manner, the cooling of the shield member 51 as described above cannot be performed. That is, for example, in addition to the fact that the heat transfer fluid L cannot appropriately flow, the shield member 51 and the sidewall 10a cannot be brought into direct contact with each other. In view of this fact, it is preferable that the heat insulating layer formed between the shield member 51 and the sidewall 10a be the vacuum heat insulating space 50s.

In the above embodiment, although the induction heating coil 52 is formed of a circular coil member and the magnetic substance 53 is formed of a rectangular plate member, the shapes of the induction heating coil 52 and the magnetic substance 53 are not limited thereto, as long as the magnetic substance 53 can be heated by induction heating. That is, for example, the induction heating coil 52 may be formed in a rectangular shape, or may be configured by a plate member. Further, the magnetic substance 53 may be formed in, for example, a circular shape, or may be configured by a coil member.

In this manner, although the induction heating coil 52 and the magnetic substance 53 can be configured in any shape, from the viewpoint of uniformly controlling the temperature of the wall surface of the shield member 51 and the atmosphere temperature in the plasma processing space 10s, it is preferable that the shapes of the induction heating coil 52 and the magnetic substance 53 be formed in a shape (for example, a rectangular disposition or a honeycomb disposition) in which the induction heating coil 52 and the magnetic substance 53 can be evenly laid on the entire surface of the shield member 51.

In the above embodiment, although the shield member 51 is disposed to cover the entire surface of the sidewall 10a of the plasma processing chamber 10 and the magnetic substance 53 is disposed in at least a part of the inside of the shield member 51 as illustrated in FIG. 6, the configuration of the heating mechanism 50 is not limited thereto.

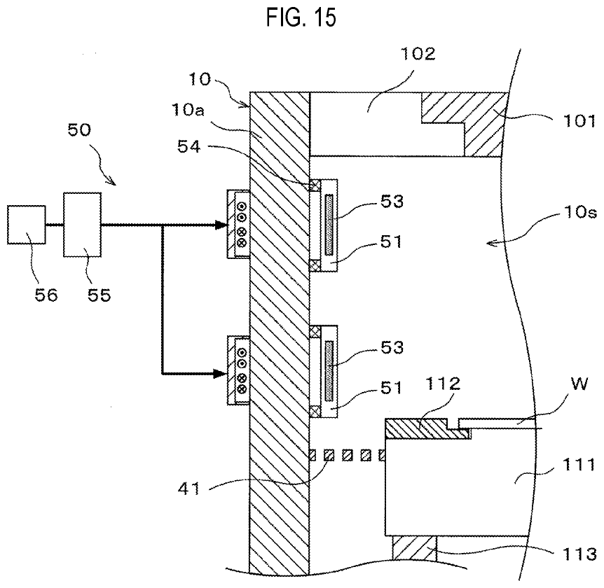

For example, the shield member 51 does not need to be disposed to cover the entire surface of the sidewall 10a, and may be disposed in at least a part of the sidewall 10a, for example, only in a range in which the magnetic substance 53 is provided, as illustrated in FIG. 15. In other words, the shield member 51 does not need to constitute the entire inner wall surface of the plasma processing space 10s, and may constitute at least a part of the inner wall surface. In this case, the plasma processing space 10s is defined by the dielectric window 101, the sidewall 10a, the shield member 51 of the heating mechanism 50, and the substrate support 11.

In the above embodiment, although the heating mechanism 50 is disposed along the sidewall 10a of the plasma processing chamber 10 such that the shield member 51 forms the inner wall surface of the plasma processing space 10s, the disposition of the heating mechanism 50 is not limited thereto.

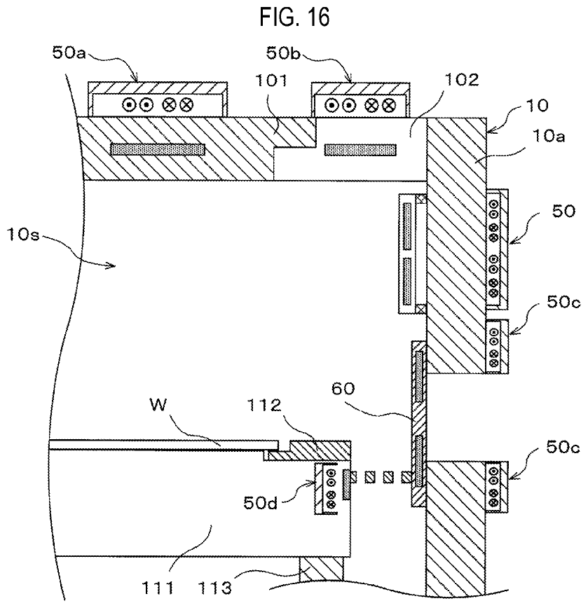

Specifically, as illustrated in FIG. 16, the heating mechanism 50 may be further provided in a member forming the plasma processing space 10s, which is a portion that is exposed to plasma during the plasma processing and thus may cause adhesion of the deposition.

More specifically, for example, as illustrated in FIG. 16, a heating mechanism 50a disposed to heat the dielectric window 101 constituting the ceiling portion of the plasma processing chamber 10 may be provided. In this case, the magnetic substance 53 may be provided inside the shield member 51 which is thermally separated from the dielectric window 101 by the method illustrated in FIG. 2, or may be disposed directly inside the dielectric window 101 as illustrated in FIG. 16. Even in this case, since a heat capacity of the dielectric window 101 is at least smaller than a heat capacity of the sidewall 10a of the plasma processing chamber 10, the heating of the dielectric window 101 can be appropriately performed.

Further, for example, as illustrated in FIG. 16, a heating mechanism 50b disposed to heat the insulator ring 102 provided between the dielectric window 101 and the sidewall 10a may be provided. In this case, the magnetic substance 53 may be disposed directly inside the insulator ring 102. Further, for example, in a case where the insulator ring 102 is small and it is difficult to dispose the magnetic substance 53 inside, the insulator ring 102 may be indirectly heated by heating the dielectric window 101 or the sidewall 10a in the vicinity of the insulator ring 102.

Further, for example, as illustrated in FIG. 16, a heating mechanism 50c disposed to heat the shutter 60 constituting at least a part of the sidewall 10a of the plasma processing chamber 10 may be provided. In this case, the magnetic substance 53 may be disposed directly inside the shutter 60, or the shutter 60 may be indirectly heated by heating the sidewall 10a in the vicinity of the shutter 60. Meanwhile, in a case where the magnetic substance 53 is disposed directly inside the shutter 60, the induction heating coil 52 for heating the magnetic substance 53 cannot be disposed at an opening forming the loading port 60a. Therefore, the induction heating coil 52 for heating the magnetic substance 53 disposed inside the shutter 60 may be disposed along, for example, a periphery of the loading port 60a at the outer wall surface of the sidewall 10a, as illustrated in FIG. 16.

Further, for example, as illustrated in FIG. 16, a heating mechanism 50d disposed to heat the baffle plate 41 that partitions the plasma processing space 10s and the gas exhaust port 10e may be provided. In this case, the magnetic substance 53 may be disposed directly inside the baffle plate 41, or the baffle plate 41 may be indirectly heated by heating the sidewall 10a or the substrate support 11 in the vicinity of the baffle plate 41, as illustrated in FIG. 16.

As described above, as illustrated in FIG. 16, the heating mechanism 50 may be disposed to heat various members constituting the plasma processing space 10s, in addition to or instead of the shield member 51 provided along the sidewall 10a. In this manner, by adjusting the temperature of the inner surface of the plasma processing chamber 10 constituting the plasma processing space 10s, the deposition on an inner surface of the plasma processing chamber 10 (the plasma processing space 10s) can be easily controlled. In other words, the plasma processing can be stably performed on the substrate W.

Further, in the above embodiment, although the heating mechanism 50 is disposed to heat the members forming the plasma processing space 10s, the heating mechanism 50 may also be disposed at another portion.

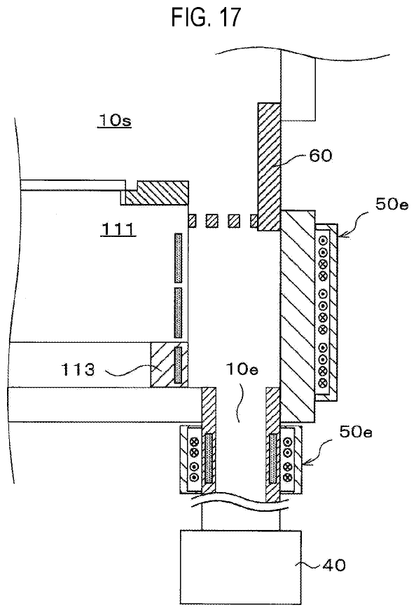

Specifically, as illustrated in FIG. 17, a heating mechanism 50e disposed to heat a wall surface portion of an exhaust space formed downstream of an exhaust path from the baffle plate 41 inside the plasma processing chamber 10 (more specifically, the substrate support 11 constituting the lower electrode, the support member 113 of the substrate support 11, or a wall surface portion of the plasma processing chamber 10), or the vicinity of the gas exhaust port 10e may be provided.

The deposition may adhere to the downstream side of the exhaust path from the baffle plate 41 due to, for example, the transmission of the plasma from the plasma processing space 10s or the influence of impurity or the like included in the exhaust. Therefore, by providing the downstream side of the exhaust path to be temperature-adjustable by the heating mechanism 50 in this manner, it is possible to appropriately reduce the adhesion of such deposition.

In the above embodiment, although the case where the shutter 60, which opens and closes the loading port 60a, is provided at a part of the sidewall 10a of the plasma processing chamber 10 in a circumferential direction is described by way of example, the configuration of the shutter mechanism is not limited thereto.

Specifically, for example, the shutter mechanism according to another embodiment may be configured with the shutter 60, which opens and closes the loading port 60a illustrated in FIG. 1, and the shield member 51 of the heating mechanism 50 integrated with each other.

Further, in the example illustrated in FIG. 17, although the temperature adjustment of the exhaust path is performed by the heating mechanism 50 disposed in the support member 113, instead of or in addition to this configuration, the temperature adjustment may be configured to heat an inner peripheral side of the support member 113, that is, a lower space of the substrate support 11.

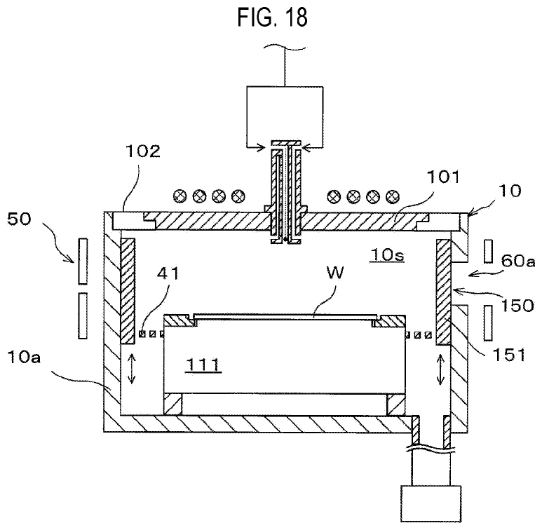

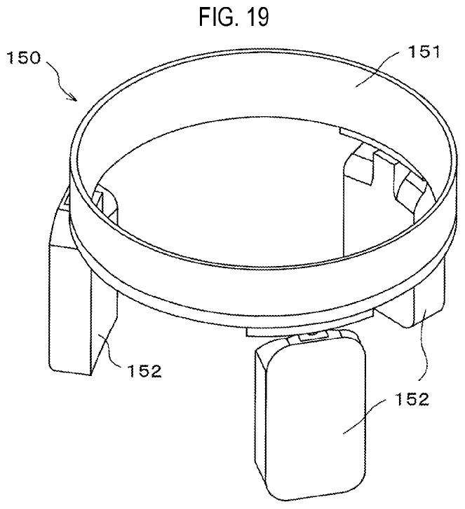

FIGS. 18 and 19 are a vertical cross-sectional view and a perspective view illustrating a schematic configuration of a shutter mechanism 150 according to another embodiment. As illustrated in FIGS. 18 and 19, the shutter mechanism 150, which opens and closes the loading port 60a, may include a valve body 151 in which a shutter and a deposition shield are integrated with each other, and a lifter 152 causing the valve body 151 to be vertically moved.

The valve body 151 is provided with an annular valve body extending along an inner periphery of the sidewall 10a of the plasma processing chamber 10. That is, the valve body 151 is disposed to surround an entire periphery of the substrate support 11 disposed inside the plasma processing chamber 10. The valve body 151 is configured to be vertically movable by an operation of the lifter 152, and can be moved between a closed position and a retracted position of the loading port 60a by an elevating operation.

Further, as described above, the valve body 151 is disposed to cover at least a part of the sidewall 10a of the plasma processing chamber 10 when the loading port 60a is closed, and may function as a shield member functioning substantially as an inner wall surface of the plasma processing space 10s.

Further, even in a case where the shutter mechanism 150 is provided in this manner, that is, even in a case where the valve body 151 is configured in an annular shape, the heating mechanism 50 according to the technique of the present disclosure can be applied. In other words, the heating mechanism 50 may be provided to heat the shutter mechanism 150. In this case, the magnetic substance 53 may be disposed directly inside the valve body 151, or the valve body 151 may be indirectly heated by heating the sidewall 10a in the vicinity of the valve body 151.

Further, for example, in a case where the valve body 151 is provided at the shutter mechanism 150 as illustrated in FIG. 18, the heating mechanism 50 may be disposed to heat an entire portion other than a position at which the loading port (opening) of the substrate W is formed at the sidewall 10a of the plasma processing chamber 10, that is, a portion other than a portion facing the opening in an interior space of the plasma processing chamber 10.

In the above embodiment, although the case where the temperature adjustment of the shield member 51 is performed during the plasma processing performed in the plasma processing apparatus 1 is described by way of example, the timing for adjusting the temperature of the shield member 51 is not limited thereto. Specifically, for example, after a cleaning process of the plasma processing apparatus 1 is performed, the heating of the shield member 51 may be performed before the substrate W is loaded.

Immediately after the cleaning process of the plasma processing apparatus 1, a cleaning liquid used for the cleaning process may remain in the plasma processing chamber 10. In this case, chemical effects such as corrosion may occur at a remaining location of the cleaning liquid, or the deposition generated by the plasma processing may be accumulated. Further, in a case where the cleaning liquid remaining during the plasma processing is scattered and adheres to the substrate W, a process result of the substrate W may deteriorate.

In the plasma processing apparatus 1 of the present embodiment, the cleaning liquid remaining in the plasma processing chamber 10 is removed by heating the shield member 51 after the cleaning process and before the substrate is loaded. Accordingly, it is possible to reduce the occurrence of the problems caused by the remaining cleaning liquid described above. Further, in the present embodiment, since the heating of the shield member 51 is performed without heating the sidewall 10a of the plasma processing chamber 10 as described above, the temperature of the shield member 51 can be immediately raised to a temperature necessary for the removal of the cleaning liquid. That is, since the heating efficiency of the shield member 51 is appropriate, a time required for the start-up of the plasma processing apparatus 1 can be appropriately reduced.

It shall be understood that the embodiments disclosed herein are illustrative and are not restrictive in all aspects. The embodiment described above may be omitted, replaced, or modified in various forms without departing from the scope and spirit of the appended claims.

For example, in the above embodiment, although the case where the atmosphere temperature (the surface temperature of the shield member 51) in the processing space is adjusted by the heating mechanism 50 in the plasma processing apparatus 1 that performs the plasma processing on the substrate W is described by way of example, the type of the substrate processing apparatus in which the heating mechanism 50 is disposed is not limited thereto. As the processing apparatus in which the heating mechanism 50 is disposed, for example, a thermal treatment apparatus such as a chemical vapor deposition (CVD) apparatus or an annealing apparatus, or a transfer device that transfers the substrate W can be freely selected. In particular, any processing apparatus that requires adjustment of the atmosphere temperature of the processing space (or the temperature of the sidewall of the processing chamber) during the substrate processing can appropriately have the effects of the technology according to the present disclosure.

What is claimed is:

1. A substrate processing apparatus for processing a substrate, the substrate processing apparatus comprising:
a processing chamber in which a processing space for the substrate is formed;
a heating mechanism that adjusts an inner temperature of the processing chamber; and
an inner member provided inside the processing chamber,
wherein the heating mechanism includes:
an induction heating element that heats at least the inner member by generating heat with an induction magnetic field; and
a magnetic field generator that generates the induction magnetic field.

2. The substrate processing apparatus according to claim 1,
wherein the inner member is a shield member disposed apart from an inner wall surface of the processing chamber and defining at least a part of a sidewall portion of the processing space, and
wherein the magnetic field generator is disposed along an outer wall surface of the processing chamber.

3. The substrate processing apparatus according to claim 2, further comprising:
a heat insulating layer that provides heat insulation between the shield member and the inner wall surface of the processing chamber.

4. The substrate processing apparatus according to claim 3,
wherein a vacuum heat insulating space serving as the heat insulating layer is formed between the shield member and the inner wall surface of the processing chamber.

5. The substrate processing apparatus according to claim 4, further comprising:
a fluid supply that supplies a heat transfer fluid to the vacuum heat insulating space; and
a fluid exhausting portion through which the heat transfer fluid is exhausted from the vacuum heat insulating space.

6. The substrate processing apparatus according to claim 2,
wherein the induction heating element is disposed inside the shield member.

7. The substrate processing apparatus according to claim 2,
wherein the induction heating element is disposed at a wall surface on a side of the heat insulating layer in the shield member.

8. The substrate processing apparatus according to claim 2, further comprising:
a shutter mechanism including:
a valve body that opens and closes a substrate loading port formed at a sidewall portion of the processing chamber, and
a lifter that causes the valve body to be vertically moved inside the processing chamber,
wherein the shield member is integrally formed with the valve body of the shutter mechanism.

9. The substrate processing apparatus according to claim 1,
wherein the inner member is a substrate holder that is disposed inside the processing chamber and holds the substrate on an upper surface of the substrate holder.

10. The substrate processing apparatus according to claim 1,
wherein, in a front view, the induction heating element is disposed such that at least a part of the induction heating element overlaps with the magnetic field generator.

11. The substrate processing apparatus according to claim 1,
wherein the induction heating element is formed of a plate member or a coil member; and,
wherein the induction heating element is made of an iron-containing material containing any of carbon steel, silicon steel, stainless steel, permalloy, and ferrite, or at least one of aluminum, tungsten, tin, titanium, carbon, silicon, or silicon carbide.

12. The substrate processing apparatus according to claim 1,
wherein the substrate processing apparatus includes a plurality of the induction heating elements and a plurality of the magnetic field generators, and
wherein the inner member is configured to be independently heated for each of a plurality of predetermined temperature control regions.

13. The substrate processing apparatus according to claim 12,
wherein the induction heating elements and the magnetic field generators are provided in a same number such that one of the magnetic field generators corresponds to one of the induction heating elements.

14. The substrate processing apparatus according to claim 12,
wherein the plurality of induction heating elements correspond to one magnetic field generator.

15. The substrate processing apparatus according to claim 1,
wherein the substrate processing apparatus is a plasma processing apparatus for performing plasma processing on the substrate,
wherein a plurality of the heating mechanisms are disposed in the plasma processing apparatus, and
wherein the plurality of heating mechanisms heats at least one of a dielectric window that forms a ceiling portion of the processing space, an insulator ring that connects the dielectric window and the processing chamber, an exhaust space for exhausting a gas inside the processing space, a baffle plate that partitions the processing space and the exhaust space, and a shutter mechanism that opens and closes a substrate loading port formed in a sidewall portion of the processing chamber.

16. The substrate processing apparatus according to claim 1,
wherein a magnetic shield that reduces transmission of the induction magnetic field is provided to surround the magnetic field generator in a front view; and
wherein the magnetic shield is made of a member having a relative magnetic permeability equal to or less than 1.

17. The substrate processing apparatus according to claim 1,
wherein a magnetic shield that reduces transmission of the induction magnetic field is provided outside the processing chamber with the magnetic field generator interposed between the magnetic shield and the processing chamber.

18. The substrate processing apparatus according to claim 1, further comprising:
an actuator that causes a part of the magnetic field generator to come close to or separate from the induction heating element.

19. A substrate processing method performed by a substrate processing apparatus including a processing chamber in which a processing space for a substrate is formed, a shield member disposed apart from an inner wall surface of the processing chamber and defining at least a part of a sidewall portion of the processing space, a heat insulating layer that provides heat insulation between the shield member and the inner wall surface of the processing chamber, an induction heating element that heats at least the shield member by generating heat with an induction magnetic field, and a magnetic field generator that is disposed outside the processing chamber and generates the induction magnetic field, the substrate processing method comprising:
generating an induction magnetic field by supplying a current to the magnetic field generator, and heating the shield member with the induction magnetic field; and
adjusting an amount of the current supplied to the magnetic field generator, based on at least one of an atmosphere temperature of the processing chamber and an amount of reaction products adhered to the shield member.

20. The substrate processing method according to claim 19,
wherein a vacuum heat insulating space serving as the heat insulating layer is formed between the shield member and the inner wall surface of the processing chamber, and
wherein the substrate processing method further comprises:
cooling the shield member by supplying a heat transfer fluid into the vacuum heat insulating space.
